(19) United States
(12) Patent Application Publication
(10) Pub. No.: US 2025/0332681 A1
(43) Pub. Date: Oct. 30, 2025

(54) POLISHING APPARATUS

(71) Applicant: EBARA CORPORATION, Tokyo (JP)

(72) Inventors: Yuta SUZUKI, Tokyo (JP); Taro TAKAHASHI, Tokyo (JP); Katsuhide WATANABE, Tokyo (JP); Nobuyuki TAKADA, Tokyo (JP)

(21) Appl. No.: 18/870,045

(22) PCT Filed: Mar. 22, 2023
(86) PCT No.: PCT/JP2023/011153

§ 371 Date: Nov. 27, 2024

(30) Foreign Application Priority Data
Jun. 2, 2022 (JP) 2022-090066

(51) Int. Cl. B24B 37/013; B24B 7/22; B24B 49/16

(52) U.S. Cl. CPC B24B 37/013; B24B 7/228; B24B 49/16

(57) ABSTRACT

The present application relates to a polishing apparatus. The polishing apparatus includes a three-axis sensor arranged adjacent to a head arm and configured to detect information on forces in three axes directions acting on a polishing head.

### TECHNICAL FIELD

The present invention relates to a polishing apparatus.

### BACKGROUND ART

A Chemical Mechanical Polishing (CMP) is known as a technique in a manufacturing process of semiconductor devices. A polishing apparatus for performing the CMP includes a polishing table that supports a polishing pad and a polishing head that holds a wafer.

When the wafer is polished using such a polishing apparatus, the wafer is held by the polishing head and pressed against a polishing surface of the polishing pad with a predetermined pressure. At this time, the polishing table and the polishing head are moved relative to each other to bring the wafer into sliding contact with the polishing surface, thereby polishing a surface of the wafer.

### CITATION LIST

### Patent Literature

Patent document 1: Japanese laid-open patent publication No. 2021-091090

### SUMMARY OF INVENTION

### Technical Problem

When the wafer is polished, a frictional force occurs between the wafer and the polishing pad. By monitoring this frictional force, it is possible to control a pressing force of the polishing head and to determine a polishing end point of the wafer. For example, in a state in which the wafer having a laminated upper layer film and lower layer film is polished, when the upper layer film is removed by polishing, the lower layer film is exposed. By monitoring the frictional force, a point at which the lower layer film is exposed can be determined as the polishing end point.

A torque current of the table motor that rotates the polishing table changes according to the frictional force generated between the wafer and the polishing pad. There is a method for determining the frictional force based on the change in the torque current, but such a method has a large error range of the current due to a machine difference in the motor and an assembly variation of the polishing head. As a result, there is a risk that the frictional force generated between the wafer and the polishing pad cannot be determined with high accuracy.

Therefore, the present invention provides a polishing apparatus capable of accurately determining the frictional force generated between the wafer and the polishing pad.

### Solution to Problem

In an embodiment, there is provided a polishing apparatus comprising: a polishing table configured to support a polishing pad; a polishing head configured to press a substrate against the polishing table; a head shaft coupled to the polishing head; a head arm configured to rotatably support the head shaft; and a three-axis sensor arranged adjacent to the head arm and configured to detect information on forces acting on the polishing head in three axial directions.

In an embodiment, the polishing apparatus comprises a control device electrically connected to the three-axis sensor, and the control device is configured to monitor a frictional force generated between the substrate and the polishing head during polishing of the substrate, the frictional force being calculated based on a signal sent from the three-axis sensor.

In an embodiment, the control device is configured to: measure a tilt of the substrate based on the signal sent from the three-axis sensor; and control an attitude of the polishing head based on the measured tilt of the substrate.

In an embodiment, the control device is configured to: compare the calculated frictional force with a predetermined threshold value; and when the frictional force reaches the threshold value, determine a polishing end point of the substrate.

In an embodiment, the polishing apparatus comprises a localized load application device electrically connected to the control device, which is configured to apply a localized load to a portion of a retaining ring of the polishing head, and the control device is configured to: calculate the frictional force generated between the substrate and the polishing head based on the signal sent from the three-axis sensor; and control an operation of the localized load application device based on the calculated frictional force.

In an embodiment, there is provided a polishing apparatus comprising: a polishing table configured to support a polishing pad; a polishing head configured to press a substrate against the polishing table; a head shaft coupled to the polishing head; a head arm configured to rotatably support the head shaft; a first housing plate and a second housing plate arranged on both side of the head arm; a first sensor group arranged between the first housing plate and the head arm and configured to detect information on a force acting on the polishing head; and a second sensor group arranged between the second housing plate and the head arm and configured to detect information on a force acting on the polishing head.

In an embodiment, each of the first sensor group and the second sensor group comprises a plurality of force sensors, and the force sensors are arranged at equal distances from the head shaft.

In an embodiment, the polishing apparatus comprises a control device electrically connected to the first sensor group and the second sensor group, and the control device is configured to monitor a frictional force generated between the substrate and the polishing head during polishing of the substrate, the frictional force being calculated based on signals sent from the first sensor group and the second sensor group.

In an embodiment, the control device is configured to: measure a tilt of the substrate based on the signals sent from the first sensor group and the second sensor group; and control an attitude of the polishing head based on the measured tilt of the substrate.

In an embodiment, the control device is configured to: compare the calculated frictional force with a predetermined threshold value; and when the frictional force reaches the threshold value, determine a polishing end point of the substrate.

In an embodiment, the polishing apparatus comprises a localized load application device electrically connected to the control device, which is configured to apply a localized load to a portion of a retaining ring of the polishing head, and the control device is configured to: calculate the frictional force generated between the substrate and the polishing head based on the signals sent from the first sensor group and the second sensor group; and control an operation of the localized load application device based on the calculated frictional force.

### Advantageous Effects of Invention

The polishing apparatus includes a sensor that detects information on the force acting on the polishing head. Therefore, the polishing apparatus can accurately determine the frictional force generated between the wafer held by the polishing head and the polishing pad.

### BRIEF DESCRIPTION OF DRAWINGS

FIG. 1 is a view showing an embodiment of a polishing apparatus;

FIG. 2 is a view showing a first sensor group and a second sensor group;

FIG. 3 is a view showing an example of a component of a frictional force acting between a polishing head and a wafer;

FIG. 4 is a view showing a change in the frictional force;

FIG. 5 is a view showing an example of the component of the frictional force acting between the polishing head and the wafer;

FIG. 6 is a view showing a state in which the wafer is tilted with respect to a polishing pad; and

FIG. 7 is a view showing another embodiment of the polishing apparatus.

### DESCRIPTION OF EMBODIMENTS

Hereinafter, embodiments of the present invention will be described in detail with reference to the drawings.

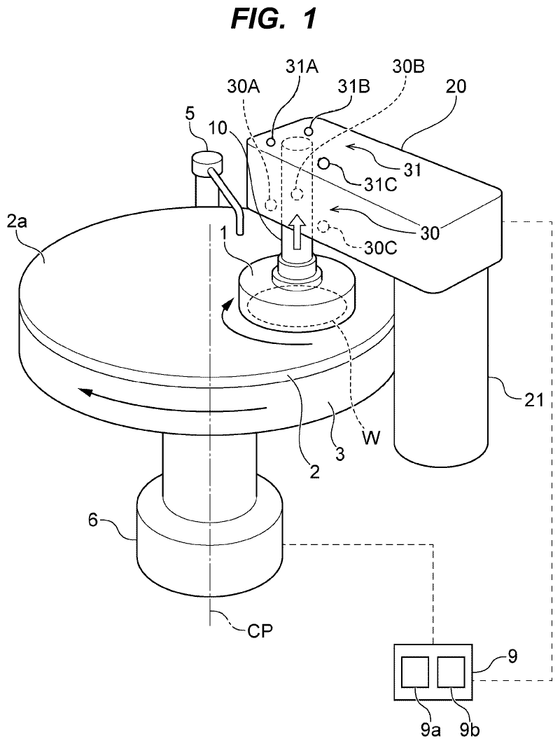

FIG. 1 is a view showing an embodiment of a polishing apparatus. As shown in FIG. 1, the polishing apparatus includes a polishing table 3 that supports a polishing pad 2, a polishing head 1 that presses a wafer W (such as a substrate) having a film against the polishing pad 2, a table motor 6 that rotates the polishing table 3, a polishing liquid supply nozzle 5 for supplying a polishing liquid such as slurry onto the polishing pad 2, and a control device 9 for controlling operations of the polishing apparatus. An upper surface of the polishing pad 2 forms a polishing surface 2a for polishing the wafer W. The control device 9 is electrically connected to the table motor 6.

The polishing head 1 is coupled to a head shaft 10, and the head shaft 10 is coupled to a polishing head motor (not shown) via a coupling means such as a belt. The polishing head motor rotates the polishing head 1 together with the head shaft 10 in a direction indicated by an arrow.

The head shaft 10 is coupled to a head arm 20 that rotatably supports the head shaft 10, and is configured to move up and down relative to the head arm 20 by a vertical movement mechanism (not shown). The head arm 20 is coupled to an arm shaft 21, and is pivotable about the arm shaft 21. The polishing table 3 is coupled to the table motor 6, and the table motor 6 is configured to rotate the polishing table 3 and the polishing pad 2 in directions indicated by arrows.

The wafer W is polished as follows. While the polishing table 3 and the polishing head 1 are rotated in the direction indicated by the arrow in FIG. 1, the polishing liquid is supplied from the polishing liquid supply nozzle 5 onto the polishing surface 2a of the polishing pad 2 on the polishing table 3. While the wafer W is rotated around the head shaft 10 by the polishing head 1, the wafer W is pressed against the polishing surface 2a of the polishing pad 2 by the polishing head 1 in a state in which the polishing liquid presents on the polishing pad 2. The polishing table 3 rotates around its center CP. A surface of the wafer W is polished by a chemical action of the polishing liquid and a mechanical action of abrasive grains contained in the polishing liquid or the polishing pad 2.

The control device 9 is composed of at least one computer. The control device 9 includes a storage device 9a in which a program is stored, and a calculation device 9b that executes calculations according to instructions included in the program. The calculation device 9b includes a CPU (Central Processing Unit) or a GPU (Graphics Processing Unit) that executes calculations according to instructions included in the program stored in the storage device 9a. The storage device 9a includes a main storage device (e.g., random access memory) that can be accessed by the calculation device 9b, and an auxiliary storage device (e.g., a hard disk drive or a solid state drive) that stores data and programs.

It is important to accurately determine the frictional force generated between the wafer W and the polishing pad 2 in order to accurately control the pressing force of the polishing head 1 and accurately determine the polishing end point of the wafer W. Therefore, in this embodiment, the polishing apparatus includes a first sensor group 30 and a second sensor group 31 arranged adjacent to the head arm 20 in order to accurately determine the frictional force. Configurations of these sensor groups 30 and 31 will be described below with reference to the drawings.

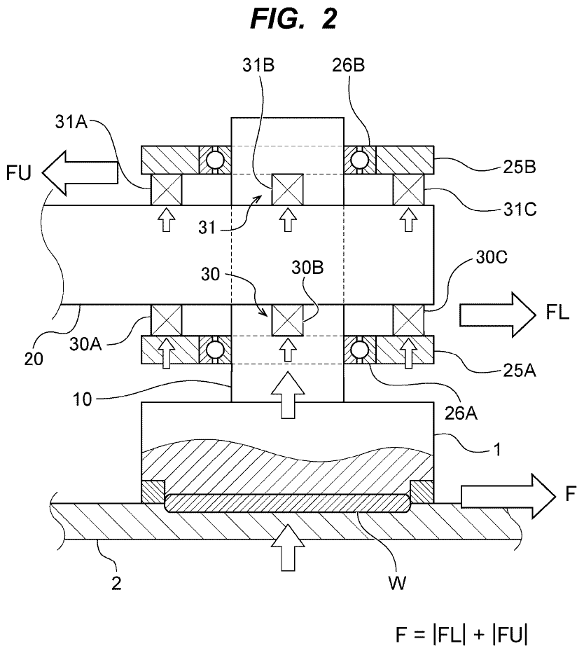

FIG. 2 is a view showing the first sensor group and the second sensor group. As shown in FIG. 2, the first sensor group 30 and the second sensor group 31 are each arranged on a tip side of the head arm 20 (i.e., a side coupled to the head shaft 10).

The polishing apparatus includes a first housing plate 25A and a second housing plate 25B arranged on both sides of the head arm 20 (above and below the head arm 20 in the embodiment shown in FIG. 2). In FIG. 1, these housing plates 25A and 25B are omitted for ease of viewing, but the polishing apparatus also includes the housing plates 25A and 25B in the embodiment shown in FIG. 1.

The housing plates 25A and 25B have the same structure. Each of the housing plates 25A and 25B has a flat plate shape extending parallel to the head arm 20. The first housing plate 25A is arranged below the head arm 20, and the second housing plate 25B is arranged above the head arm 20.

As shown in FIG. 2, the first sensor group 30 is arranged between the first housing plate 25A and the head arm 20, and is configured to detect information on the force acting on the polishing head 1. More specifically, the first sensor group 30 includes a plurality of force sensors 30A, 30B, and 30C. These force sensors 30A, 30B, and 30C are arranged around the head shaft 10, and are arranged at equal distances from the head shaft 10 (see FIGS. 1 and 2). The force sensors 30A, 30B, and 30C are arranged in a same plane above the first housing plate 25A.

The second sensor group 31 has a configuration similar to that of the first sensor group 30. The second sensor group 31 is arranged between the second housing plate 25B and the head arm 20, and is configured to detect information on the force acting on the polishing head 1. More specifically, the second sensor group 31 includes a plurality of force sensors 31A, 31B, and 31C. These force sensors 31A, 31B, and 31C are arranged around the head shaft 10, and are arranged at equal distances from the head shaft 10 (see FIGS. 1 and 2). The force sensors 31A, 31B, and 31C are arranged in the same plane below the second housing plate 25B.

In the embodiment shown in FIGS. 1 and 2, each of the first sensor group 30 and the second sensor group 31 includes three force sensors, but the number of force sensors is not limited to the embodiment. The number of force sensors may be determined according to a size of the polishing head 1 and the pressing force of the polishing head 1. In an embodiment, each of the first sensor group 30 and the second sensor group 31 may include at least one force sensor.

In the embodiment shown in FIGS. 1 and 2, each of the force sensors 30A, 30B, and 30C (and the force sensors 31A, 31B, and 31C) is a triaxial sensor that detects information on forces in three axial directions (i.e., x-axis, y-axis, and z-axis) acting on the polishing head 1. An example of the triaxial sensor is a quartz-type piezoelectric element. Where, the x-axis direction and the y-axis direction are directions that extend perpendicular to the head shaft 10 (i.e., directions that extend parallel to the polishing pad 2), and in this embodiment, they are horizontal directions. The z-axis direction is a direction that extends parallel to the head shaft 10 (i.e., a direction that extends perpendicular to the polishing pad 2), and in this embodiment, it is a vertical direction.

In one embodiment, each of the force sensors 30A, 30B, and 30C (and the force sensors 31A, 31B, and 31C) may be a biaxial sensor that detects information on the force in two axial directions (i.e., the x-axis and the y-axis), or a uniaxial sensor that detects information on the force in one axial direction (i.e., the z-axis). In an embodiment, each of the force sensors 30A, 30B, and 30C (and the force sensors 31A, 31B, and 31C) may be a combination of a biaxial sensor and a uniaxial sensor. With such a configuration, the polishing apparatus can also accurately determine the frictional force.

As shown in FIG. 2, the head shaft 10 passes through a through hole formed in center portions of the housing plates 25A and 25B. The polishing apparatus includes a first bearing 26A arranged between the head shaft 10 and the first housing plate 25A, and a second bearing 26B arranged between the head shaft 10 and the second housing plate 25B.

Each of the bearings 26A and 26B is configured to receive a load (more specifically, a radial load and an axial load (i.e., a thrust load)) of the polishing head 1 through the head shaft 10. When the polishing head 1 presses the wafer W against the polishing pad 2, the load of the polishing head 1 acts on each of the force sensors 30A, 30B, 30C, 31A, 31B, and 31C.

In the embodiment, the polishing apparatus has a structure in which the head shaft 10 is supported by each of the housing plates 25A and 25B (and the bearings 26A and 26B), and the sensor groups 30 and 31 are sandwiched between the housing plates 25A and 25B and the head arm 20. With this structure, the polishing apparatus can uniformly transmit the load acting on the polishing head 1 to each of the sensor groups 30 and 31 via the head shaft 10.

By arranging a plurality of force sensors in spaces formed above and below the head arm 20, it is possible to employ force sensors having a compact size, and as a result, it is possible to realize space saving in the polishing apparatus. Furthermore, with such a configuration, it is possible to employ a plurality of force sensors having a compact size and high resolution, and as a result, it is possible to detect information on the force acting on the polishing head 1 with higher accuracy.

The control device 9 is electrically connected to each of the force sensors 30A, 30B, 30C, 31A, 31B, and 31C. The control device 9 calculates the load of the polishing head 1 based on a signal detected by each of the force sensors 30A, 30B, 30C, 31A, 31B, and 31C, and calculates a frictional force F acting on the wafer W from the calculated load of the polishing head 1. As shown in FIG. 2, the frictional force F is a sum of an absolute value of a force component FL acting on the force sensors 30A, 30B, and 30C and an absolute value of the force component FU acting on the force sensors 31A, 31B, and 31C (F=|FL|+|FU|).

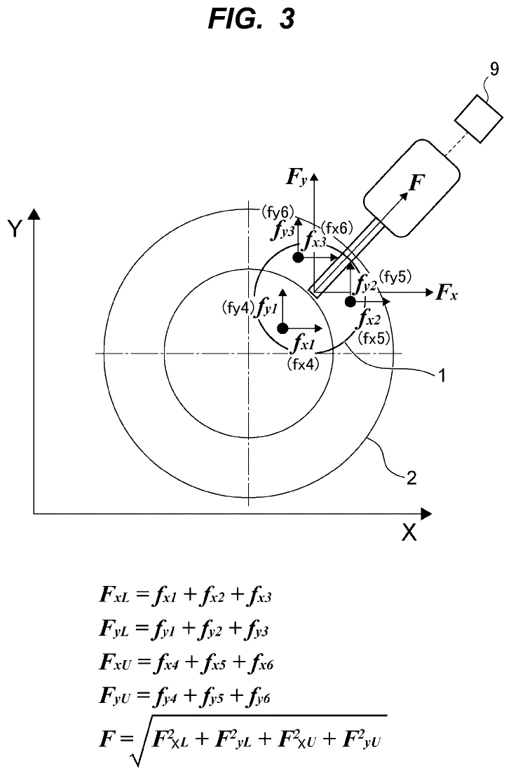

FIG. 3 is a view showing an example of a component of the frictional force acting between the polishing head and the wafer. As shown in FIG. 3, when the polishing head 1 is viewed from above, a force component of the x-axis acting on the force sensors 30A, 30B, 30C, 31A, 31B, and 31C are defined as fx₁, fx₂, fx₃, fx₄, fx₅, and fx₆, and a force component of the y-axis are defined as fy₁, fy₂, fy₃, fy₄, fy₅, and fy₆.

A force component FxL of the x-axis acting on the force sensors 30A, 30B, and 30C is expressed as fx₁+fx₂+fx₃, and a force component FyL of the y-axis is expressed as fy₁+fy₂+fy₃. A force component FxU of the x-axis acting on the force sensors 31A, 31B, and 31C is expressed as fx₄+fx₅+fx₆, and a force component FyU of the y-axis is expressed as fy₄+fy₅+fy₆.

A combined force component F (i.e., the frictional force generated between the polishing pad 2 and the wafer W) acting on the force sensors 30A, 30B, 30C and the force sensors 31A, 31B, 31C in the x-axis and the y-axis directions, which are perpendicular to each other, is expressed by a following equation 1.

$$[ Math . 1 ]$$

$$F = \sqrt{{F}^{2} xL + {F}^{2} yL + {F}^{2} xU + {F}^{2} yU} \qquad equation 1$$

The control device 9 stores data relating to the above equation 1 in the storage device 9a. Therefore, the control device 9 calculates the frictional force F based on the signal sent from each force sensor belonging to the sensor groups 30 and 31 and the above equation 1. The control device 9 may constantly monitor the calculated frictional force F during polishing of the wafer W. By monitoring the frictional force F, the control device 9 can accurately determine the polishing end point of the wafer W in accordance with a change in the frictional force F.

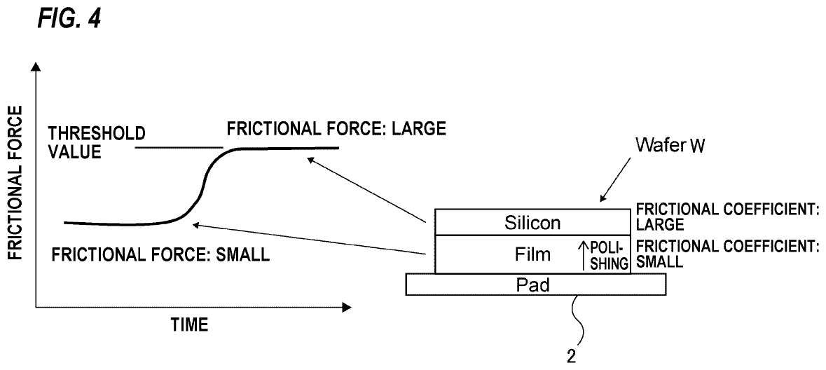

FIG. 4 is a view showing the change in the frictional force. In the embodiment shown in FIG. 4, the wafer W has an upper layer film and a lower layer film laminated together. Since the upper layer film is made of a material softer than the lower layer film, the frictional force generated between the upper layer film and the polishing pad 2 is smaller than the frictional force generated between the lower layer film and the polishing pad 2. When the wafer W is continuously polished, the upper layer film is eventually removed and the lower layer film is exposed. As shown in a graph of FIG. 4, when the lower layer film is exposed, the frictional force F changes. Note that the graph of FIG. 4 is a graph showing the change in the frictional force F over time.

The control device 9 can determine the polishing end point (i.e., a point in time when the lower layer film is exposed) by monitoring the frictional force F during polishing of the wafer W. More specifically, the control device 9 stores a threshold value corresponding to a type of film on the wafer W to be polished in the storage device 9a. The threshold value is a value equivalent to the frictional force at the polishing end point. The control device 9 compares the calculated frictional force F with a predetermined threshold value, and when the current frictional force F reaches the threshold value, determines the polishing end point of the wafer W.

In the embodiment shown in FIG. 4, since the upper layer film is made of a material softer than the lower layer film, the frictional force F larges as polishing of the wafer W progresses, but depending on the type of wafer W, the upper layer film may be made of a material harder than the lower layer film. In this case, the frictional force F smalls as polishing of the wafer W progresses. Even in this case, the control device 9 compares the calculated frictional force F with a predetermined threshold value, and when a current frictional force F reaches the predetermined threshold value, determines the polishing end point of the wafer W.

Although the control device 9 may determine the frictional force based on a change in the torque current of the table motor 6, there is a risk that the frictional force cannot be determined accurately due to a machine difference in the motor and a variation in an assembly of the polishing head 1. According to the embodiment, the control device 9 determines the frictional force F based on the force sensor that detects information on the force acting on the polishing head 1. Therefore, the control device 9 can accurately determine the frictional force F generated between the wafer W held by the polishing head 1 and the polishing pad 2.

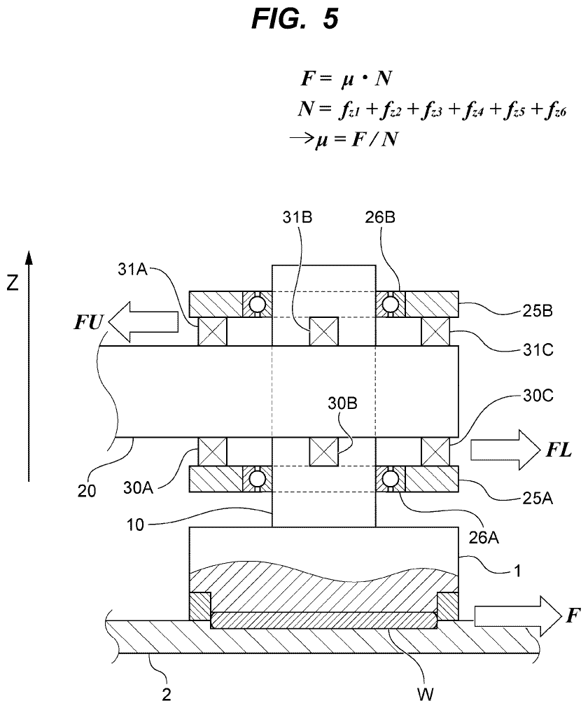

FIG. 5 is a view showing an example of the component of the frictional force acting between the polishing head and the wafer. As shown in FIG. 5, the force component of the z-axis acting on the force sensors 30A, 30B, 30C, 31A, 31B, and 31C are defined as fz₁, fz₂, fz₃, fz₄, fz₅, and fz₆. The force component (i.e., normal force) N of the z-axis acting on the force sensors 30A, 30B, 30C, 31A, 31B, and 31C is expressed as fz₁+fz₂+fz₃+fz₄+fz₅+fz₆ (N=fz₁+fz₂+fz₃+fz₄+fz₅+fz₆).

The frictional force F generated between the polishing pad 2 and the wafer W is expressed by the following equation 2.

$$F = μ \times N \qquad equation 2$$

Where, μ represents a frictional coefficient. The frictional coefficient μ differs depending on the type of the wafer W, and further changes during polishing of the wafer W. Therefore, the control device 9 may determine (estimate) the frictional coefficient μ to an arbitrary value, and determine the frictional force F based on the determined frictional coefficient μ and the normal force N. With such a method, the control device 9 can also determine the frictional force F with high accuracy.

In this embodiment, each of the force sensors 30A, 30B, 30C, 31A, 31B, and 31C is a three-axis sensor. Therefore, the control device 9 can derive the frictional force F from the above equation 1 and calculate the normal force N, thereby deriving the frictional coefficient μ from the above equation 2. The control device 9 can obtain a more accurate the frictional force F from the frictional coefficient μ and the normal force N.

Since the above equation 2 includes the frictional coefficient μ, a proportional relationship according to the frictional coefficient μ is established between the above equation 1 and the above equation 2. Therefore, the control device 9 can determine an abnormality of the force sensor (and/or an abnormality in the assembly of the polishing head 1) by comparing the frictional force F derived from the equation 1 with the frictional force F derived from the equation 2. More specifically, the control device 9 may compare the two frictional forces F derived from the above equation 1 and equation 2 during polishing of the wafer W, and if the proportional relationship is not established between these two frictional forces F, determine that an abnormality has occurred in at least one of the force sensors 30A, 30B, 30C, 31A, 31B, and 31C.

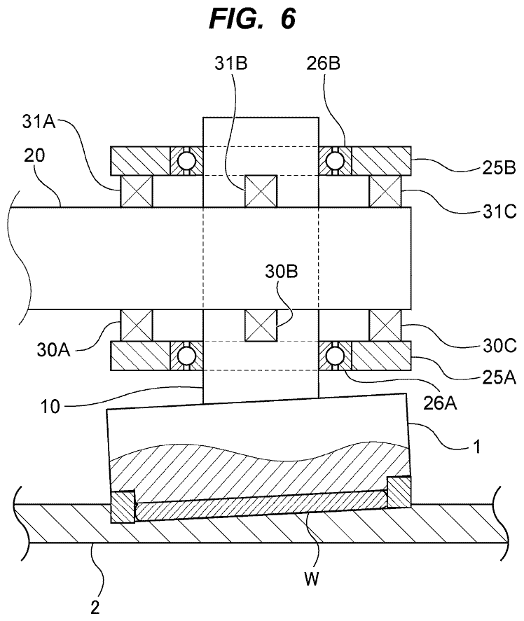

FIG. 6 is a view showing a state in which the wafer is tilted with respect to the polishing pad. As shown in FIG. 6, the wafer W may be tilted with respect to the polishing pad 2 during polishing of the wafer W. If the wafer W is continued to be polished in this state, not only will the uniformity of the film thickness of the wafer W decrease, but the polishing end point of the wafer W may not be determined accurately. More specifically, if the wafer W is tilted, the upper layer film may not be polished uniformly, and a part of the lower layer film may be exposed while the upper layer film is partially left. In this case, the wafer W is polished with a mixture of a part of the upper layer film and a part of the lower layer film, so that the frictional force F changes gradually with time, and even when the frictional force F reaches a threshold value, the polishing end point of the wafer W may not be reached.

Therefore, the control device 9 may calculate the normal force N acting on each force sensor based on the signals sent from the force sensors 30A, 30B, 30C, 31A, 31B, and 31C, and measure the tilt of the wafer W from these normal forces N. By arranging a plurality of force sensors belonging to the sensor groups 30 and 31 around the head shaft 10, the control device 9 can accurately measure the tilt of the wafer W.

The control device 9 may control an attitude of the polishing head 1 based on the measured the tilt of the wafer W. The polishing head 1 includes an elastic membrane (not shown) for pressing the wafer W against the polishing surface 2a of the polishing pad 2. Therefore, the control device 9 may supply a pressurizing gas to the elastic membrane to control the attitude of the polishing head 1 so that the polishing head 1 is parallel to the polishing pad 2.

Furthermore, according to the embodiment, the control device 9 can determine whether or not the pressing force of the polishing head 1 acting on the entire wafer W is uniform based on the signals sent from each of the multiple force sensors. If the signals sent from the force sensors are different, the control device 9 can determine that the pressing force of the polishing head 1 is not uniform. In this case, the control device 9 may supply the pressurizing gas to the elastic membrane to control the pressing force of the polishing head 1 so that the pressing force of the polishing head 1 becomes uniform.

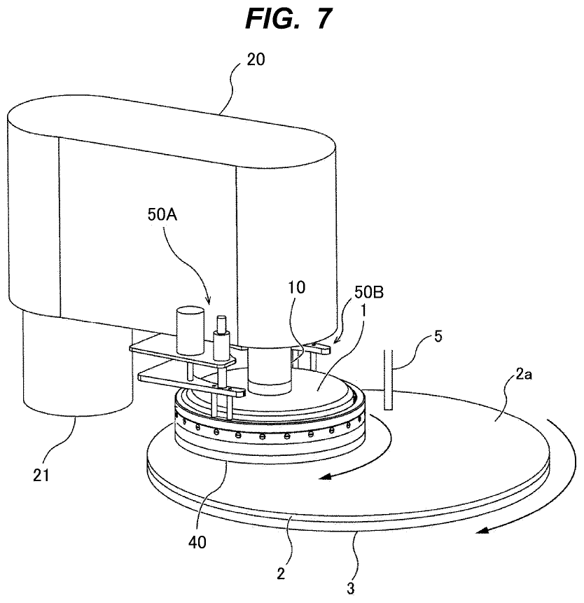

FIG. 7 is a view showing another embodiment of the polishing apparatus. In the embodiment shown in FIG. 7, the polishing head 1 includes a retaining ring 40 that surrounds the wafer W. As shown in FIG. 7, the polishing apparatus includes a first localized load application device 50A that applies a localized load to a portion of the retaining ring 40, and a second localized load application device 50B that applies a localized load to a portion of the retaining ring 40.

The localized load application devices 50A and 50B are arranged above the retaining ring 40 and fixed to the head arm 20. Therefore, while the retaining ring 40 rotates about its axis during polishing, the localized load application devices 50A and 50B do not rotate together with the retaining ring 40 but remain stationary.

The first localized load application device 50A is arranged upstream of the retaining ring 40 (one side of the retaining ring 40 where the polishing liquid flows into the polishing surface 2a) in a traveling direction of the polishing surface 2a of the polishing pad 2, and the second localized load application device 50B is arranged downstream of the retaining ring 40 (the opposite side of the retaining ring 40 where the polishing liquid flows out of the polishing surface 2a) in the traveling direction of the polishing surface 2a of the polishing pad 2. The control device 9 is electrically connected to each of the localized load application devices 50A and 50B, and each of the localized load application devices 50A and 50B applies a downward localized load on the portion of the retaining ring 40.

When the polishing liquid flows between the wafer W and the polishing pad 2, the frictional force generated between the wafer W and the polishing pad 2 may differ between the upstream side and the downstream side of the retaining ring 40. It is desirable that the frictional force acting on the wafer W is uniform over the entire wafer W. Therefore, the control device 9 may calculate the frictional force F acting on the entire wafer W based on the signal sent from each of the force sensors, and when the frictional force F differs between the upstream side and the downstream side of the retaining ring 40, control an operation of each of the localized load application devices 50A and 50B. With this configuration, the control device 9 can make the frictional force acting on the entire wafer W uniform and maintain the frictional force constant.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The invention is applicable to a polishing apparatus.

### REFERENCE SIGNS LIST

1 polishing head
2 polishing pad
2a polishing surface
3 polishing table
5 polishing liquid supply nozzle
6 table motor
9 control device
9a storage device
9b calculation device
10 head shaft
20 head arm
25A first housing plate
25B second housing plate
30 first sensor group
30A, 30B, 30C force sensor
31 second sensor group
31A, 31B, 31C force sensor
40 retaining ring
50A first localized load application device
50B second localized load application device

1. A polishing apparatus comprising:
a polishing table configured to support a polishing pad;
a polishing head configured to press a substrate against the polishing table;
a head shaft coupled to the polishing head;
a head arm configured to rotatably support the head shaft; and
a three-axis sensor arranged adjacent to the head arm and configured to detect information on forces acting on the polishing head in three axial directions.

2. The polishing apparatus according to claim 1,
wherein the polishing apparatus comprises a control device electrically connected to the three-axis sensor, and
wherein the control device is configured to monitor a frictional force generated between the substrate and the polishing head during polishing of the substrate, the frictional force being calculated based on a signal sent from the three-axis sensor.

3. The polishing apparatus according to claim 2,
wherein the control device is configured to:
measure a tilt of the substrate based on the signal sent from the three-axis sensor; and
control an attitude of the polishing head based on the measured tilt of the substrate.

4. The polishing apparatus according to claim 2,
wherein the control device is configured to:
compare the calculated frictional force with a predetermined threshold value; and
when the frictional force reaches the threshold value, determine a polishing end point of the substrate.

5. The polishing apparatus according to claim 2,
wherein the polishing apparatus comprises a localized load application device electrically connected to the control device, which is configured to apply a localized load to a portion of a retaining ring of the polishing head, and
wherein the control device is configured to:
calculate the frictional force generated between the substrate and the polishing head based on the signal sent from the three-axis sensor; and
control an operation of the localized load application device based on the calculated frictional force.

6. A polishing apparatus comprising:
a polishing table configured to support a polishing pad;
a polishing head configured to press a substrate against the polishing table;
a head shaft coupled to the polishing head;
a head arm configured to rotatably support the head shaft;
a first housing plate and a second housing plate arranged on both side of the head arm;
a first sensor group arranged between the first housing plate and the head arm and configured to detect information on a force acting on the polishing head; and
a second sensor group arranged between the second housing plate and the head arm and configured to detect information on a force acting on the polishing head.

7. The polishing apparatus according to claim 6,
wherein each of the first sensor group and the second sensor group comprises a plurality of force sensors, and
wherein the force sensors are arranged at equal distances from the head shaft.

8. The polishing apparatus according to claim 6,
wherein the polishing apparatus comprises a control device electrically connected to the first sensor group and the second sensor group, and
wherein the control device is configured to monitor a frictional force generated between the substrate and the polishing head during polishing of the substrate, the frictional force being calculated based on signals sent from the first sensor group and the second sensor group.

9. The polishing apparatus according to claim 8,
wherein the control device is configured to:
measure a tilt of the substrate based on the signals sent from the first sensor group and the second sensor group; and
control an attitude of the polishing head based on the measured tilt of the substrate.

10. The polishing apparatus according to claim 8,
wherein the control device is configured to:
compare the calculated frictional force with a predetermined threshold value; and
when the frictional force reaches the threshold value, determine a polishing end point of the substrate.

11. The polishing apparatus according to claim 8,
wherein the polishing apparatus comprises a localized load application device electrically connected to the control device, which is configured to apply a localized load to a portion of a retaining ring of the polishing head, and
wherein the control device is configured to:
calculate the frictional force generated between the substrate and the polishing head based on the signals sent from the first sensor group and the second sensor group; and
control an operation of the localized load application device based on the calculated frictional force.
